(19) United States
(12) Patent Application Publication
(10) Pub. No.: US 2011/0266625 A1
(43) Pub. Date: Nov. 3, 2011

(54) Maintaining Integrity of a High-K Gate Stack After Embedding a Stressor Material by Using a Liner

(75) Inventors: Richard Carter, Dresden (DE); Sven Beyer, Dresden (DE); Markus Lenski, Dresden (DE); Patrick Press, Dresden (DE)

(73) Assignee: GLOBALFOUNDRIES INC., Grand Cayman (KY)

(21) Appl. No.: 12/963,253

(22) Filed: Dec. 8, 2010

(30) Foreign Application Priority Data
Apr. 30, 2010 (DE) 10 2010 028 466.1

(51) Int. Cl. H01L 29/78; H01L 21/336

(52) U.S. Cl. 257/365; 438/283; 257/E21.409; 257/E29.264

(57) ABSTRACT

Gate failures in sophisticated high-k metal gate electrode structures formed in an early manufacturing stage may be reduced by forming a protective liner material after the incorporation of a strain-inducing semiconductor alloy and prior to performing any critical wet chemical processes. In this manner, attacks in the sensitive gate materials after the incorporation of the strain-inducing semiconductor material may be avoided, without influencing the further processing of the device. In this manner, very sophisticated circuit designs may be applied in sophisticated gate first approaches.

### BACKGROUND OF THE INVENTION

1. Field of the Invention

Generally, the present disclosure relates to the fabrication of highly sophisticated integrated circuits including advanced transistor elements that comprise strain-inducing semiconductor alloys and gate structures of increased capacitance including a high-k gate dielectric and a metal-containing cap layer.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of integrated circuits, field effect transistors represent one important type of circuit element that substantially determines performance of the integrated circuits. Generally, a plurality of process technologies are currently practiced for forming field effect transistors, wherein, for many types of complex circuitry, CMOS technology is one of the most promising approaches due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the mobility of the charge carriers in the channel region.

The continuous shrinkage of critical dimensions of transistor elements has resulted in a gate length of field effect transistors of 50 nm and significantly less, thereby providing sophisticated semiconductor devices having enhanced performance and an increased packing density. The increase of electrical performance of the transistors is strongly correlated with a reduction of the channel length, which may result in an increased drive current and switching speed of the field effect transistors. On the other hand, the reduction of the channel length is associated with a plurality of issues in terms of channel controllability and static leakage currents of these transistors. It is well known that field effect transistors with a very short channel may require an increased capacitive coupling between the gate electrode structure and the channel region in order to provide the desired static and dynamic current flow controllability. Typically, the capacitive coupling is increased by reducing the thickness of the gate dielectric material, which is typically formed on the basis of a silicon dioxide based material, possibly in combination with a nitrogen species, due to the superior characteristics of a silicon/silicon dioxide interface. Upon implementing a channel length of the above-identified order of magnitude, however, the thickness of the silicon dioxide based gate dielectric material may reach values of 1.5 nm and less, which in turn may result in significant leakage currents due to a direct tunneling of the charge carriers through the very thin gate dielectric material. Since the exponential increase of the leakage currents upon further reducing the thickness of silicon dioxide based gate dielectric materials is not compatible with the thermal power design requirements, other mechanisms have been developed so as to further enhance transistor performance and/or reduce the overall transistor dimensions.

For example, by creating a certain strain component in the channel region of silicon based transistor elements, the charge carrier mobility and, thus, the overall conductivity of the channel may be enhanced. For a silicon material with a standard crystallographic configuration, i.e., a (100) surface orientation with the channel length direction oriented along a <110> equivalent direction, tensile strain in the current flow direction may enhance conductivity of electrons, thereby improving transistor performance of N-channel transistors. On the other hand, generating a compressive strain in the current flow direction may increase the mobility of holes and may thus provide superior conductivity in P-channel transistors. Consequently, a plurality of strain-inducing mechanisms have been developed in the past, which per se require a complex manufacturing sequence for implementing these techniques. Upon further device scaling, internal strain-inducing sources, such as an embedded strain-inducing semi-conductor material, may represent a very efficient strain-inducing mechanism. For example, frequently, the incorporation of a compressive strain-inducing silicon/germanium alloy in the drain and source areas of P-channel transistors is applied in order to enhance performance of these transistors. For this purpose, in an early manufacturing stage, cavities are formed in the active region laterally adjacent to the gate electrode structure of the P-channel transistor, while the N-channel transistors are covered by a spacer layer. These cavities may be subsequently refilled with the silicon/germanium alloy on the basis of selective epitaxial growth techniques. During the etch process for forming the cavities and during the subsequent epitaxial growth process, the gate electrode of the P-channel transistor has to be encapsulated in order to not unduly expose sensitive materials of the gate electrode structure, such as a silicon based electrode material, to the process ambient for forming the cavities and for selectively growing the silicon/germanium alloy. Thereafter, the gate electrode structures may be exposed and the further processing may be continued by forming drain and source regions in accordance with any appropriate process strategy.

Basically, the above-described strain-inducing mechanism is a very efficient concept for improving transistor performance of P-channel transistors, wherein the efficiency of the finally obtained strain in the channel region of the transistor, however, strongly depends on the internal strain level of the semiconductor alloy and on the lateral offset of this material from the channel region. Typically, the material composition of the strain-inducing semiconductor alloy is restricted by currently available sophisticated selective epitaxial deposition recipes, which, in the case of a silicon/germanium alloy, may presently not allow germanium concentrations of more than approximately 30 atomic percent. Consequently, a further improvement of the total strain in the channel region requires a reduction of the lateral offset of the silicon/germanium alloy from the channel region so that any protective spacer structures may have to be provided with a reduced width.

In addition to providing strain-inducing mechanisms in sophisticated field effect transistors, sophisticated gate electrode materials have also been proposed in order to overcome the restrictions of conventional silicon dioxide/polysilicon based gate electrode structures. To this end, the conventional silicon dioxide based gate dielectric material is replaced, at least partially, by a so-called high-k dielectric material, i.e., a dielectric material having a dielectric constant of 10.0 and higher, which may result in a desired high capacitance between the gate electrode and the channel region, while nevertheless a certain minimum physical thickness may be provided so as to keep the resulting leakage currents at an acceptable level. For this purpose, a plurality of dielectric materials, such as hafnium oxide based materials, zirconium oxide, aluminum oxide and the like, are available and may be used in sophisticated gate electrode structures. Furthermore, the polysilicon material may also be replaced, at least in the vicinity of the gate dielectric material, since, typically, polysilicon suffers from charge carrier depletion in the vicinity of the gate dielectric material, which may reduce the effective capacitance. Moreover, with sophisticated high-k gate dielectric materials, the work function of standard polysilicon materials and a corresponding doping may no longer be sufficient to provide the required electronic characteristics of the gate electrode material in order to obtain a desired threshold voltage of the transistors under consideration. For this reason, specific work function adjusting metal species, such as aluminum, lanthanum and the like, are typically incorporated in the gate dielectric material and/or in an appropriate electrode material in order to obtain a desired work function and also increase conductivity of the gate electrode material, at least in the vicinity of the gate dielectric material.

Thus, a plurality of sophisticated process strategies have been developed, wherein, in some promising approaches, the sophisticated gate materials, such as a high-k dielectric material and a metal-containing electrode material, possibly including a work function adjusting metal species, may be provided in an early manufacturing stage in combination with a polysilicon material, thereby providing a high degree of compatibility with conventional process strategies for forming sophisticated field effect transistors. It turns out, however, that a reliable confinement of the sensitive material system including the high-k dielectric material and the metal-containing electrode material has to be guaranteed in order to avoid a shift in threshold voltage or any other variabilities of the sophisticated high-k metal gate electrode structures.

In an attempt to further enhance device performance of sophisticated field effect transistors, it has been proposed to combine sophisticated high-k metal gate electrode structures with a strain-inducing mechanism, for instance, by incorporating a strain-inducing semiconductor alloy in the active regions of the transistors. In this case, the encapsulation of the gate electrode structure of the transistor, which may require the incorporation of an embedded strain-inducing semiconductor alloy, may have to be implemented on the basis of detrimental requirements. On the one hand, the confinement of the gate electrode structure has to ensure integrity of the sensitive material system, for example, prior to, during and after the incorporation of the strain-inducing semiconductor material, and, on the other hand, a reduced thickness of any protective spacer elements, such as silicon nitride based materials, is to be selected in view of enhancing efficiency of the strain-inducing mechanism. Consequently, a compromise of thickness of the spacer elements and gain in performance of sophisticated transistors is typically applied.

In many conventional approaches, however, overall defectivity during the patterning of the sophisticated high-k metal gate electrode structures may require efficient wet chemical cleaning processes, for instance after incorporating the strain-inducing semiconductor material upon performing lithography and etch processes. For this purpose, an SPM solution (mixture of sulfuric acid and hydrogen peroxide) has been proven to be a very efficient cleaning agent, which, however, “efficiently” removes metal-containing electrode materials, such as titanium nitride, as are provided in the sophisticated gate electrode structure. Omitting the cleaning step on the basis of SPM or providing a less efficient cleaning recipe may significantly increase the overall defectivity, thereby resulting in a significant yield loss. Using efficient SPM cleaning solutions, however, may result in significant gate failures in sophisticated semiconductor designs, as will be described in more detail with reference to FIG. 1a.

FIG. 1a schematically illustrates a top view of a semiconductor device 100, i.e., a portion of a design of a complex semiconductor device. As shown in FIG. 1a, the device 100 or its design may comprise active regions 102A, 102C, which are to be understood as semiconductor regions, in which one or more transistors are to be formed. For example, the active region 102A comprises a transistor 150A including a gate electrode structure 130A, which is to be provided on the basis of a complex material system including a high-k dielectric material and a metal-containing electrode material, as previously discussed. The gate electrode structure 130A may, thus, represent a conductive line extending across the active region 102A and above an isolation region 102D, which laterally delineates the active regions 102A, 102C. As illustrated, the gate electrode structure 130A may further extend into and across the active region 102C. Similarly, the active region 102C may comprise a transistor 150C comprising a gate electrode structure 130C, which extends across the active region 102A and above the isolation region 102D. Moreover, according to the design requirements of the device 100, the gate electrode structure 130C may also extend above the isolation region 102D in close proximity to the active region 102A and, thus, to the transistor 150A. It should be appreciated that a length of the gate electrode structures 130A, 130C may be selected to be 50 nm and less in sophisticated applications and, hence, as illustrated in FIG. 1a, the distance between the gate electrode structure 130C and the active region 102A may be significantly less than the critical gate length. As also previously explained, for example, the transistor 150A may represent a transistor that requires the incorporation of a strain-inducing semiconductor material, such as a silicon/germanium alloy, laterally adjacent to the gate electrode structure 130A in the active region 102A.

Consequently, upon actually implementing the design of the device 100 as illustrated in FIG. 1a into a semiconductor device, a plurality of complex process steps are required for forming the sophisticated gate electrode structures 130A, 130C, including the sensitive material system, and to pattern the gate electrode structures so as to comply with the corresponding design rules. Moreover, a reliable encapsulation of the gate electrode structures 130A, 130C may be required so as to protect the sensitive material system in the gate electrode structures 130A, 130C. Additionally, cavities are to be formed in the transistor 150A and are refilled with an appropriate semiconductor alloy, as is also previously discussed.

Although the design shown in FIG. 1a, in combination with sophisticated manufacturing strategies as set forth above, may basically provide fast and powerful semiconductor devices, it turns out, however, that significant gate failures may be observed, in particular, in the transistor 150C. For example, it has been observed that, in particular, the metal-containing electrode material of the sensitive material system in the gate electrode structure 130A is significantly damaged or missing, thereby resulting in complete transistor failure of the device 150C or at least contributing to significant reduction of performance of the transistor 150C.

For this reason, in many conventional approaches, respective sidewall spacer structures provided prior to the incorporation of strain-inducing semiconductor material may be increased in width in order to enhance integrity of the sensitive gate material system. Although this approach may provide significantly reduced transistor failures, even for a complex design as shown in FIG. 1a, the loss of performance caused by significantly less efficient strain-inducing mechanisms associated with the increased spacer width, as explained above, may not be acceptable for a plurality of performance driven circuit elements. In other approaches, specifically designed silicon nitride liners are provided immediately after patterning the gate electrode structures in an attempt to enhance integrity of the gate electrode structures. It turns out, however, that, nevertheless, significant transistor failures may be observed.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which the integrity of high-k metal gate electrode structures may be enhanced by providing a thin protective liner at an appropriate manufacturing stage. To this end, the liner material may be applied after incorporating the strain-inducing semiconductor material in the active regions of transistors and prior to performing any wet chemical processes so as to reliably recover any critical surface areas of the sensitive material of the high-k metal gate electrode structure prior to exposure to efficient wet chemical processes, such as cleaning processes performed on the basis of SPM and the like. Without intending to restrict the present disclosure to the following explanation, it is assumed that the process sequence for incorporating the strain-inducing semiconductor alloy may result in the exposure of certain surface areas of the critical material system, as will be described later on in more detail, in particular for circuit designs, in which the gate electrode structure extends in close proximity to an active region having incorporated therein the strain-inducing semiconductor material. Consequently, upon re-covering the surface areas immediately after the incorporation of the strain-inducing semiconductor alloy prior to performing any critical cleaning processes, superior integrity may be achieved for the further processing of the device.

One illustrative method disclosed herein relates to forming a semiconductor device. The method comprises forming a strain-inducing semiconductor material in a cavity that is formed in an active region of a transistor. The active region is laterally delineated by an isolation region and the transistor comprises a gate electrode structure comprising a material system, wherein the material system comprises a high-k dielectric material and a metal-containing cap material. Furthermore, the method comprises forming a protective liner above the isolation structure and the active region that includes the strain-inducing semiconductor material prior to performing any wet chemical cleaning processes.

A further illustrative method disclosed herein comprises forming a first gate electrode structure on a semiconductor region of a semiconductor device and forming a second gate electrode structure on an isolation region that is positioned adjacent to the semiconductor region. Furthermore, the first and second gate electrode structures comprise a material system comprising a high-k dielectric material and a metal-containing electrode material. The method further comprises forming a cavity in the semiconductor region adjacent to the isolation region. Additionally, the method comprises forming a semiconductor material in the cavity and forming a protective liner above the semiconductor region and the isolation region after forming the semiconductor material and prior to performing a wet chemical process.

One illustrative semiconductor device disclosed herein comprises a first gate electrode structure formed on an active region and comprising a material system that comprises a high-k dielectric material and a metal-containing electrode material. The semiconductor device further comprises a second gate electrode structure formed on an isolation region that is positioned adjacent to the active region, wherein the first and the second gate electrode structures comprise a spacer structure. The semiconductor device further comprises a strain-inducing semiconductor alloy formed in the active region and adjacent to the isolation region, wherein the strain-inducing semiconductor alloy extends below a portion of the spacer structures of the first and second gate electrode structures. Additionally, the semiconductor device comprises a protective liner formed on the spacer structure and between the strain-inducing semiconductor alloy and the isolation region. Moreover, a second spacer structure is formed on the protective liner.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view or a layout of a complex semiconductor device, in which manufacturing strategies for forming sophisticated high-k metal gate electrode structures in combination with embedded strain-inducing semiconductor materials may result in significant gate failures;

FIGS. 1b-1f schematically illustrate cross-sectional views of a conventional semiconductor device during various manufacturing stages in a process flow, which has been identified as a major source of gate failure; and

FIGS. 2a-2f schematically illustrate cross-sectional views of a semiconductor device during various manufacturing stages in forming sophisticated high-k metal gate electrode structures in combination with embedded strain-inducing semiconductor materials on the basis of an appropriately applied liner material for enhancing integrity of a sensitive material system, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides semiconductor devices and manufacturing techniques in which integrity of a sensitive material system, i.e., a material system comprising a high-k dielectric material in the gate dielectric layer in combination with a metal-containing electrode material, may be enhanced by providing a thin liner material after incorporating the strain-inducing semiconductor material and prior to performing critical wet chemical processes, for instance performed on the basis of SPM and the like. The protective liner material, for instance provided in the form of a silicon nitride material, may be provided with a layer thickness of one to several nanometers, such as approximately 1.5-3.0 nm, thereby, on the one hand, reliably covering any exposed surface areas of the sensitive material system, while not unduly affecting the strain-inducing mechanism obtained on the basis of the embedded semiconductor material.

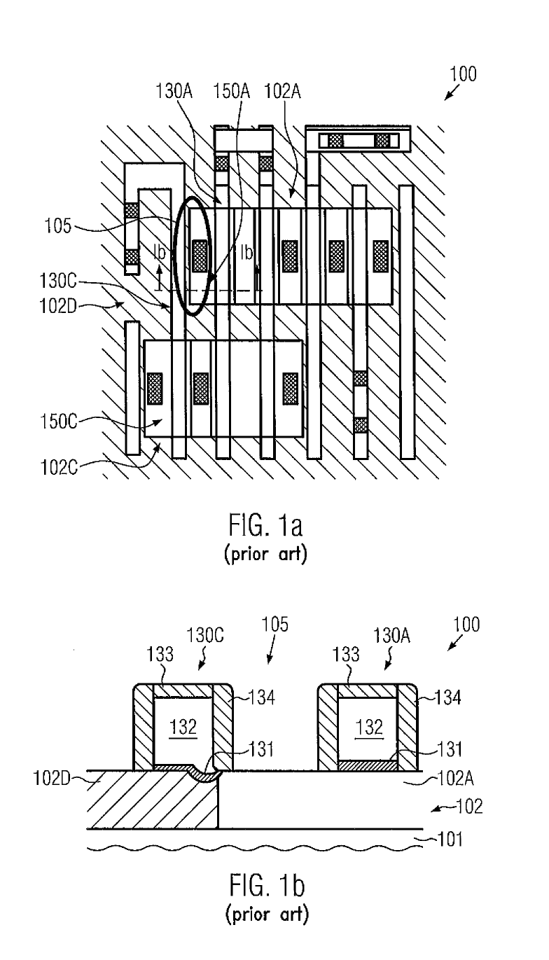

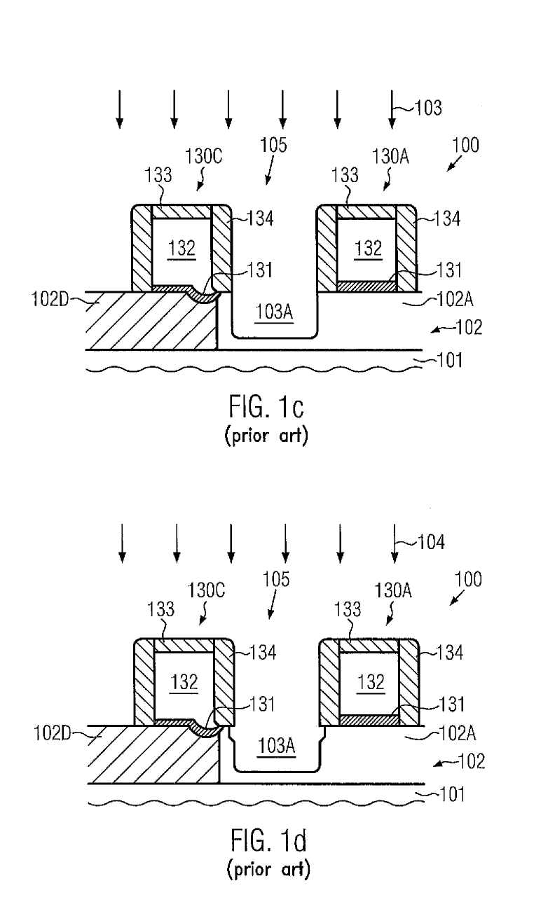

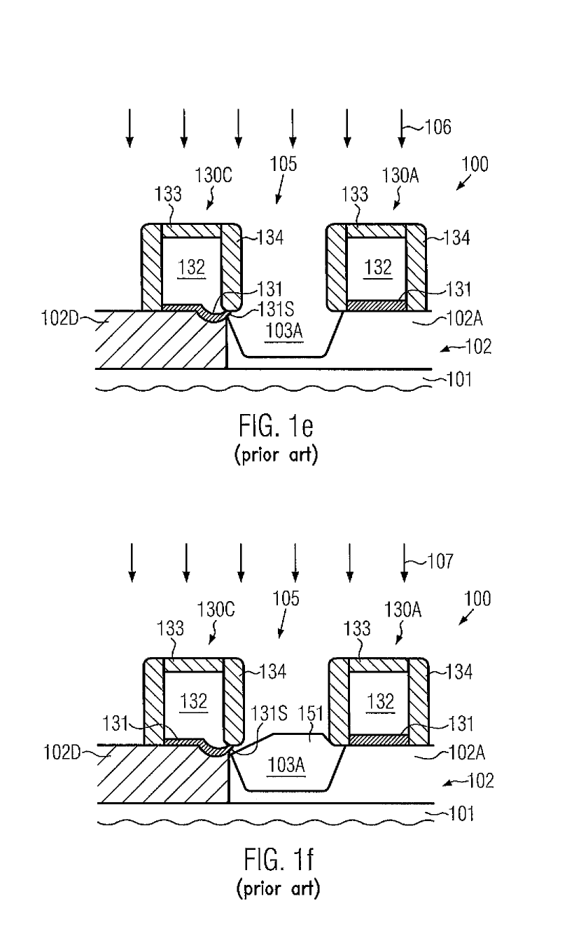

With reference to FIGS. 1b-1f, a process flow may be described in accordance with conventional process strategies in which a failure mechanism has been identified, which may result in pronounced gate failures in complex circuit designs, as are described above. It should be appreciated, however, that, although identifying a possible failure mechanism on the basis of the circuit design, as described above, represents an important step in reducing yield losses for complex semiconductor devices based on similar design criteria, the principles disclosed herein may also be advantageously applied to any circuit design in which sophisticated high-k metal gate electrode structures are to be fabricated in combination with embedded strain-inducing semiconductor materials, such as silicon/germanium, silicon/carbon and the like. Furthermore, it is strongly assumed that the failure mechanism as described below with reference to FIGS. 1b-1f may significantly contribute to transistor failures; however, a restriction of the present disclosure to any theory regarding such a failure mechanism is not intended, since the principles disclosed herein may also be readily applied to any circuit design and process flow, thereby contributing to superior production yield.

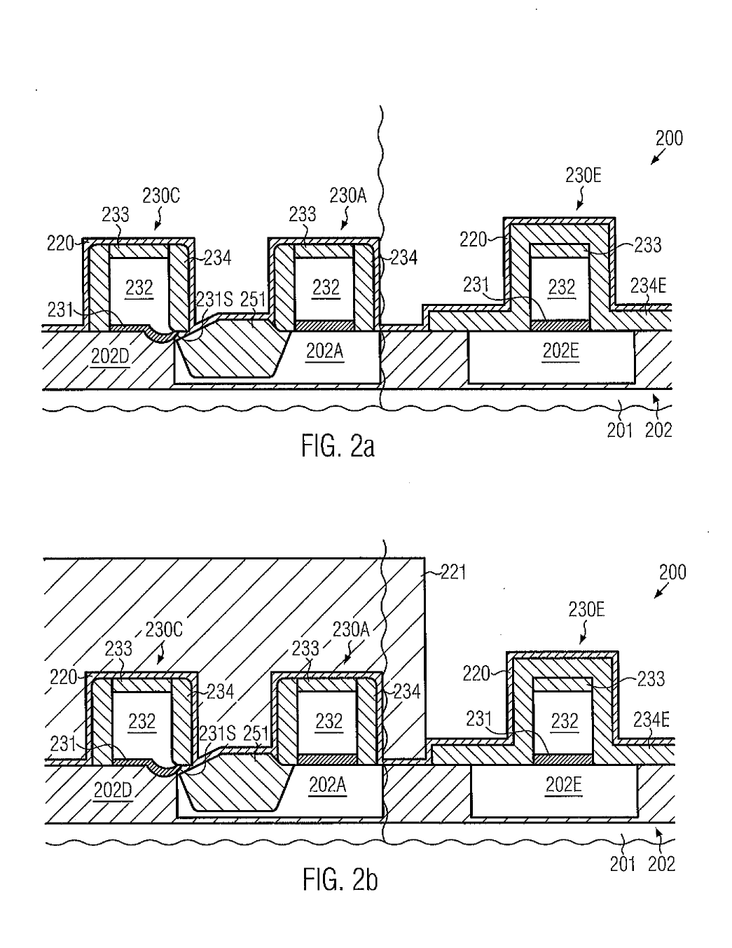

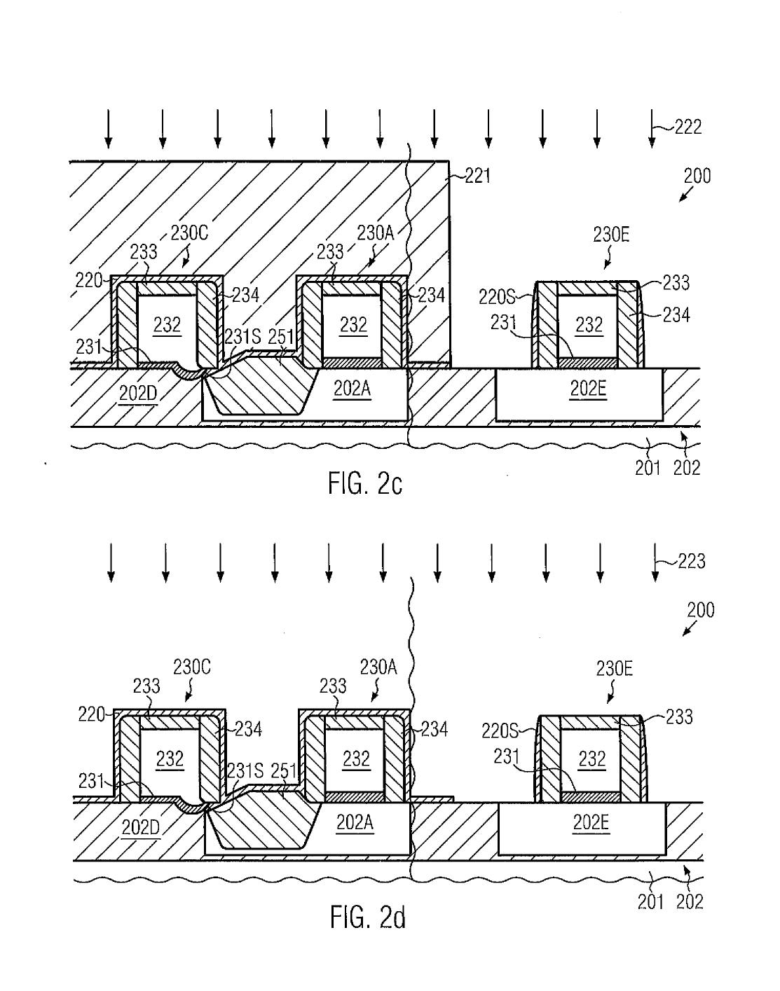

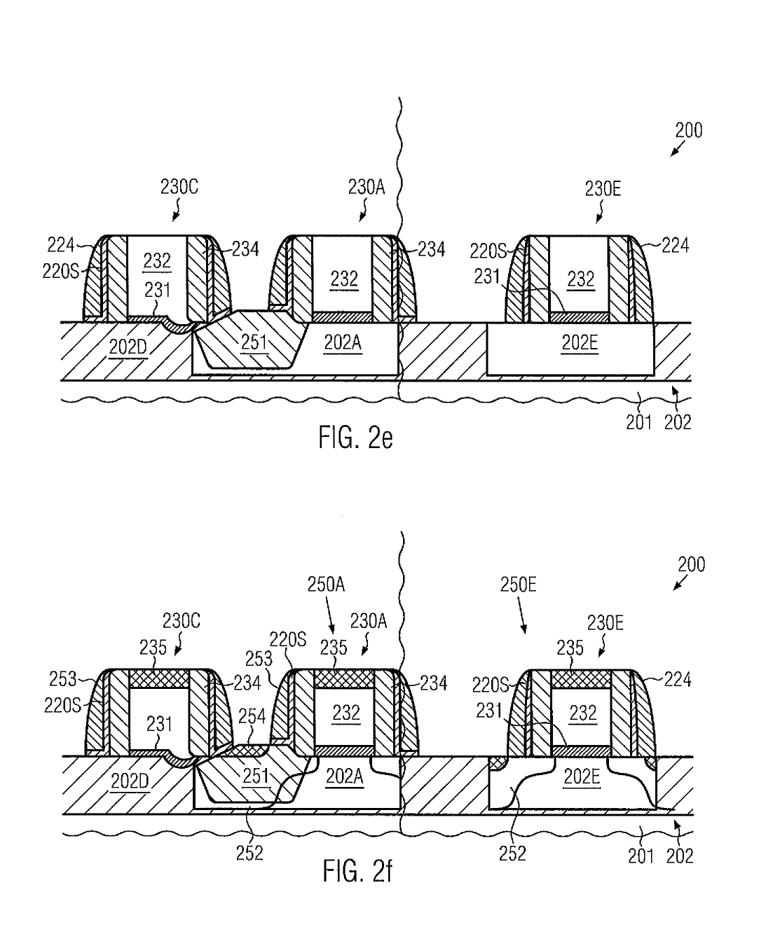

Moreover, with reference to FIGS. 2a-2f, and also referring to FIGS. 1a-1f, further illustrative embodiments will be described in more detail, wherein superior integrity may be achieved and corresponding failure mechanisms, such as the mechanism described with reference to FIGS. 1b-1f, may be neutralized or may at least be significantly reduced in their effect.

FIG. 1b schematically illustrates a cross-sectional view of the semiconductor device 100, the design of which or the top view of which is also illustrated in FIG. 1a. The cross-section is taken along the line Ib of FIG. 1a, which has been indentified as a very critical area with respect to gate failures, as will be described in the following. As illustrated, the device 100 comprises a substrate 101 and a semiconductor layer 102, which is typically provided in the form of a silicon material. The substrate 101 and the semiconductor layer 102 may form a silicon-on-insulator (SOI) architecture when a buried insulating material (not shown) is formed below the semiconductor layer 102. In other cases, a bulk configuration may be provided by the semiconductor layer 102 and the substrate 101 when the layer 102 represents a portion of a crystalline semiconductor material of the substrate 101. The semi-conductor layer 102 comprises a plurality of active regions, such as the active region 102A, and the isolation region 102D that laterally delineates the active region 102A. The isolation region 102D is typically comprised of silicon dioxide or any other appropriate dielectric material. Furthermore, as is also illustrated in FIG. 1a, the gate electrode structure 130A is formed on the active region 102A, while the gate electrode structure 130C, i.e., a corresponding portion thereof (FIG. 1a), is formed on the isolation region 102D in close proximity to the active region 102A. The gate electrode structures 130A, 130C may comprise a material system 131, which is to be understood as a gate dielectric material including a high-k dielectric material, such as hafnium oxide and the like, possibly in combination with a conventional dielectric material, such as silicon oxynitride and the like, and a metal-containing cap or electrode material, such as titanium nitride and the like, which may also include appropriate metal species in order to obtain the desired work function, as is also discussed above. It should be appreciated that the material system 131 is thus provided by two or more individual material layers, such as a silicon dioxide or oxynitride layer, followed by a high-k dielectric material layer and one or more metal-containing electrode material layers (not shown), wherein the specific composition of the material system 131 may depend on device and process requirements. Furthermore, the gate electrode structures 130A, 130C may comprise an electrode material 132, for instance in the form of a semiconductor material, such as silicon, followed by a dielectric cap material 133, such as a silicon nitride material, a silicon dioxide material, or any combination thereof, and the like. Additionally, a spacer structure 134, for instance comprised of silicon nitride, may be formed on sidewalls of the materials 132 and 131.

The semiconductor device 100 as illustrated in FIG. 1b may be formed on the basis of the following process techniques. The isolation region 102D may be formed in the semi-conductor layer 102 on the basis of well-established shallow trench isolation process techniques. Thereafter, appropriate masking regimes may be applied so as to incorporate a desired well dopant species in the various active regions, such as the active region 102A, thereby adjusting the basic transistor characteristics, such as conductivity type, threshold voltage and the like. It should be appreciated that, frequently, an additional semiconductor material, such as a silicon/germanium material and the like, may be provided in some of the active regions, such as the active region 102A, in order to obtain a desired band gap offset for transistors of different conductivity type, thereby allowing an efficient adjustment of the threshold voltages of P-channel transistors and N-channel transistors, respectively. A corresponding additional semiconductor material (not shown) may typically be provided on the basis of selective epitaxial growth techniques, wherein a certain degree of material loss may be observed in the adjacent isolation region 102D. For example, masking steps and the removal of a growth mask may be required, thereby locally creating a material loss in the isolation region 102D adjacent to the active region 102A. Thereafter, the further processing may be continued by providing material layers for the system 131, possibly in combination with additional heat treatments so as to diffuse a work function adjusting metal species and the like. Finally, the material 132 and the cap material 133, possibly in combination with additional sacrificial material, such as hard mask materials and the like, may be deposited on the basis of appropriate process techniques. Next, the complex layer stack may be patterned by using sophisticated lithography and etch techniques, followed by the deposition of a spacer layer (not shown), which may be subsequently patterned into the sidewall spacer structure 134. It should be appreciated that, in other device areas, the spacer layer may be preserved so as to act as an etch and growth mask during the further processing. As discussed above, the spacer width of the structure 134 may be selected so as to provide sufficient integrity of the materials 132 and 131, while not unduly increasing an offset of a strain-inducing semiconductor material to be incorporated in the active region 102A.

FIG. 1c schematically illustrates the device 100 during an etch process 103 for forming a cavity 103A in the active region 102A adjacent to the isolation region 102D. As illustrated, the cap materials 133 and the spacer structure 134 may act as an etch mask. The etch process 103 may be performed on the basis of any well-established etch recipe.

FIG. 1d schematically illustrates the device 100 during a cleaning process 104, in order to remove etch byproducts and any other contamination, thereby, however, also contributing to a certain material erosion at exposed sidewall surface areas in the cavity 103A.

FIG. 1e schematically illustrates the semiconductor device 100 during a further cleaning process 106, which may typically be performed prior to performing a selective epitaxial growth process, wherein any native oxides and the like may be efficiently removed during the process 106. On the other hand, a certain degree of material erosion may occur in the cavity 103A, so that a sidewall surface area 131S of the sensitive material system 131 may be exposed below the sidewall spacer structure 134 of the gate electrode structure 130C.

FIG. 1f schematically illustrates the semiconductor device 100 during a selective epitaxial growth process 107, in which a strain-inducing semiconductor material 151, such as silicon/germanium, silicon/carbon and the like, may be formed in the cavity 103A. In a selective epitaxial growth process, process parameters are selected such that material deposition is substantially restricted to exposed crystalline surface areas, i.e., surface areas of the cavity 103A, wherein a material deposition on dielectric surface areas is substantially suppressed. Consequently, due to the crystallographic growth of the material 151 within the cavity 103A, the sidewall surface 131S may remain exposed after the process 107. This exposed surface area 131S may, however, represent an access point for a wet chemical cleaning agent, such as SPM, which is known to very efficiently etch a plurality of metal-containing electrode materials, such as titanium nitride and the like.

Again referring to FIG. 1a, as indicated, the critical area 105 may be positioned close to the active region 102C and, thus, the transistor 150C. Due to the exposed sidewall surface area 131S created in the area 105, as explained above, a subsequent wet chemical etch process based on SPM may thus result in under-etching the gate electrode structure 130C starting from the region 105 towards the active region 102C, which may, thus, also result in a significant degree of material removal of the portion of the gate electrode structure 130C extending above the active region 102C. As a consequence, at least a significant modification of performance of the transistor 150C or even a total failure may be observed, although the “attack” of the wet chemical process may occur in the region 105 that is spaced apart from the transistor 150C.

Consequently, by providing an additional liner material with a reduced thickness, any exposed surface areas may be reliably re-covered after the incorporation of a strain-inducing semiconductor material and may, thus, efficiently protect the sensitive material system during any further wet chemical processes.

With reference to FIGS. 2a-2f, a corresponding process sequence will now be described in more detail, wherein reference is also made to FIGS. 1a-1f, when appropriate.

FIG. 2a schematically illustrates a cross-sectional view of a semiconductor device 200 comprising a substrate 201 and a semiconductor layer 202. The semiconductor layer 202 may comprise a plurality of active regions, such as an active region 202A and an active region 202E. Moreover, an isolation region 202D may be provided so as to laterally delineate the active regions 202A, 202E. In the embodiment shown, the active region 202A and the active region 202E may correspond to transistors of different configuration, for instance of different conductivity type, wherein it may be assumed that the transistor to be formed in and above the active region 202E may not require a strain-inducing semiconductor material or wherein a corresponding semiconductor material may be provided in a later manufacturing stage. On the other hand, a strain-inducing semiconductor material 251 may be formed in the active region 202A in order to enhance performance of any transistor to be formed in and above the active region 202A. For example, the strain-inducing semiconductor material 251 may be provided in the form of a crystalline semiconductor mixture, for instance in the form of silicon/germanium, silicon/germanium/tin, silicon/carbon and the like. It should further be appreciated that the active regions 202A, 202E may be positioned in close proximity to each other, while, in other cases, these active regions may be positioned across a semiconductor die in accordance with design requirements. Moreover, in the manufacturing stage shown, a gate electrode structure 230A may be formed on the active region 202A and a gate electrode structure 230E may be formed on the active region 202E. Furthermore, a gate electrode structure 230C may be formed on the isolation region 202D and may be positioned in close proximity to the active region 202A, for instance when a circuit design is to be used, as is previously discussed with reference to the semiconductor device 100. It should be appreciated, however, that the principles disclosed herein are not restricted to any specific circuit design, unless specifically set forth in the description or the claims.

The gate electrode structures 230A, 230C, 230E may comprise a material system 231 comprising a high-k dielectric material and a metal-containing electrode material, as is also previously discussed with reference to the semiconductor device 100. For convenience, any specific configuration of the material system 231 is not illustrated, wherein it should be appreciated, however, that two or more individual material layers may be provided in the system 231, depending on the overall device and process requirements. It should further be noted that the material system 231 may have a different configuration in the gate electrode structures 230A, 230E, wherein, however, the basic configuration may be the same, i.e., a gate dielectric material comprising a high-k dielectric component in combination with a metal-containing electrode material. Furthermore, a semiconductor-based electrode material 232, such as a silicon material, a silicon/germanium material, a germanium material and the like, may be provided in combination with a dielectric cap material 233 and a sidewall spacer structure 234.

The components described so far may be formed on the basis of any appropriate process strategy, for instance on the basis of processes as described above with reference to the semiconductor device 100. That is, the active regions 202A, 202E and the isolation structure 202D may be formed in a accordance with process techniques described above. Thereafter, the material system 231, the electrode material 232 and the dielectric cap material 233 may be provided on the basis of any appropriate process strategy, followed by a complex patterning sequence in order to pattern these materials on the basis of target critical dimensions, which may be 50 nm and significantly less. Next, a spacer layer 234E may be deposited, for instance in the form of a silicon nitride material, possibly in combination with a thin etch stop layer (not shown), and an etch mask (not shown) may be provided so as to cover the spacer layer 234E above the active region 202E, while the active region 202A and the adjacent isolation region 202D may be exposed during an etch process for forming the spacer structure 234, as is also previously discussed. Moreover, in a further etch step, cavities may be formed in the active region 202A, as is also previously described with reference to the semiconductor device 100 when describing the etch process 103 and the cavity 103A (FIG. 1c). Thereafter, cleaning processes may be performed, as previously described with reference to FIGS. 1d-1e, which may possibly cause the exposure of a sidewall surface 231S of the material system 231, for instance the material system in the gate electrode structure 230C. Thereafter, the strain-inducing semiconductor material 251 may be grown on the basis of a selective epitaxial growth process, as, for instance, also described above with reference to FIG. 1f when referring to the device 100, while the spacer layer 234E may act as an efficient growth mask. Prior to performing any critical wet chemical cleaning processes, for instance using SPM and the like, the processing may be continued by forming a protective liner material 220, thereby covering any possibly exposed surface areas of the sensitive material system 231, such as the surface area 231S. The protective liner material 220 may be formed, for instance, by any highly conformal deposition techniques, such as atomic layer deposition (ALD), multi-layer deposition, which represents a cyclic chemical vapor deposition (CVD) process technique with superior controllability of material composition and layer thickness, and the like. For this purpose, a plurality of well-established process recipes are available, for instance for forming silicon nitride, wherein a thickness may be adjusted to 1.5 to several nanometers, for instance in a range of approximately 1.5-3.0 nm. Consequently, by providing the protective liner 220 after incorporating the material 251, the thickness thereof may not contribute to the finally obtained offset of the material 251 with respect to a channel region in the active region 202A so that a desired high strain efficiency may be achieved. Moreover, due to the efficient “re-sealing” of sensitive surface areas, such as the sidewall surface 231S, the initial thickness of the spacer layer 234E may be reduced compared to conventional strategies, as for instance described above with reference to the semiconductor device 100, thereby further increasing the resulting strain in the active region 202A. That is, the thickness of the spacer layer 234E, and thus the width of the spacers 234, may be selected so as to provide efficient etch resistivity upon forming cavities in the active region 202A and providing an efficient growth mask, while efficient confinement of the sensitive materials 231, in particular at the foot of the gate electrode structures, in particular the gate electrode structure 230C, may be achieved by means of the protective liner 220.

FIG. 2b schematically illustrates the device 200 in a further advanced manufacturing stage. As illustrated, an etch mask 221, such as a resist mask, may be provided so as to cover the gate electrode structures 230C, 230A, while exposing the gate electrode structure 230E, i.e., the spacer layer 234E and the protective liner 220. Consequently, during the process sequence for providing the resist material and patterning the same, any sensitive device areas are reliably covered by the protective liner 220.

FIG. 2c schematically illustrates the semiconductor device 200 when exposed to an etch process 222, in which the protective liner 220 and the spacer layer 234E (FIG. 2b) may be patterned into spacers 234 and 220S. To this end, well-established plasma enhanced etch recipes may be applied, for instance for etching silicon nitride material selectively with respect to silicon, silicon dioxide and the like.

FIG. 2d schematically illustrates the semiconductor device 200 when exposed to a wet chemical process 223, which, in some illustrative embodiments, may be performed on the basis of SPM, thereby providing a high degree of efficiency for reducing overall defectivity, as is also previously discussed. Consequently, during the wet chemical process 223, the resist mask 221 (FIG. 2c) may be efficiently stripped, while also any contaminants may be removed. Hence, during the wet chemical process 223, in particular the sensitive surface areas 231S, or any other surface areas, which may be affected by the preceding process sequence for incorporating the strain-inducing material 251, may be reliably protected. In particular, sophisticated device configurations based on a design as previously described with reference to FIG. 1a may receive a superior degree of sealing of sensitive surface areas, such as the area 231S.

FIG. 2e schematically illustrates the semiconductor device 200 in a further advanced manufacturing stage. As illustrated, the gate electrode structures 230A, 230C may comprise spacers 220S formed from the protective liner 220 (FIG. 2d), in combination with sacrificial spacer elements 224, which may be comprised of silicon dioxide, amorphous carbon and the like, and which may be used for protecting the spacer 234 and the spacer 220S upon removing the dielectric cap material 233 (FIG. 2d). To this end, an appropriate spacer material may be deposited and may be patterned into the sacrificial spacer elements 224 by using well-established process techniques, followed by a further etch process for removing the dielectric cap materials 233 as shown in FIG. 2d. To this end, any appropriate plasma-based or wet chemical etch chemistry may be applied, for instance for removing silicon nitride material selectively with respect to silicon dioxide material. Thereafter, the sacrificial spacers 224 may be removed, for instance, by performing a wet chemical etch process based on hydrofluoric acid and the like.

FIG. 2f schematically illustrates the semiconductor device 200 in a further advanced manufacturing stage. As shown, a transistor 250A comprising the gate electrode structure 230A may be formed in and above the active region 202A, while a transistor 250E may be formed in and above the active region 202E and may comprise the gate electrode structure 230E. Similarly, a transistor (not shown) may be formed on the basis of the gate electrode structure 230C in active regions, when a corresponding design is used, as is for instance discussed above with reference to FIG. 1a. The transistors 250A 250E may comprise drain and source regions 252 of appropriate conductivity type, while a semiconductor material 251 embedded in the active region 202A may provide superior strain conditions, thereby enhancing performance of the transistor 250A, as is also discussed above. Moreover, metal silicide regions 254 may be formed in the drain and source regions 252, while metal silicide regions 235 may be formed in the gate electrode structure 230A and also in the gate electrode structures 230C and 230E. Furthermore, an additional sidewall spacer structure 253 may be formed on sidewalls of the gate electrode structures 230A, 230C and 230E. That is, the gate electrode structures 230A, 230C and 230E may comprise the spacers 234 and the spacer elements 220S, i.e., the residues of the protective liner material 220 (FIG. 2a), in combination with the structure 253, which may be used for forming the drain and source regions 252 and possibly the metal silicide regions 254.

The semiconductor device 200 as illustrated in FIG. 2f may be formed on the basis of any appropriate process strategy, for instance forming the sidewall spacer structure 253 in combination with the drain and source regions 252 using well-established masking regimes and implantation techniques. After any anneal processes, the metal silicide regions 254 and 235 may be formed in accordance with any appropriate silicidation technique.

Consequently, the transistors 250A, 250E may comprise the gate electrode structures 230A, 230E, respectively, having superior performance due to the material system 231 including a high-k dielectric material and a metal-containing electrode material provided in an early manufacturing stage, while a semiconductor-based electrode material 232 may provide a high degree of compatibility with well-established manufacturing strategies for forming polysilicon-based gate electrodes.

As a result, the present disclosure provides manufacturing techniques and semiconductor devices in which superior integrity of a sensitive material system in sophisticated high-k metal gate electrode structures may be achieved by providing a protective liner material after the incorporation of a strain-inducing semiconductor material, for instance for P-channel transistors and/or N-channel transistors, thereby reliably covering any surface areas which may have been exposed during the formation of corresponding cavities and which may not have been covered during the selective epitaxial growth process. The protective liner may be provided prior to performing any critical wet chemical processes, for instance based on SPM, so as to avoid undue material loss of the sensitive gate materials. Consequently, efficient wet chemical cleaning processes may be applied without causing undue gate failures. On the other hand, the protective liner material may be provided with a reduced thickness so as to minimize any negative influence on the further processing, while the lateral offset of the strain-inducing semiconductor material may be adjusted on the basis of a spacer structure, which may be provided with reduced width or thickness compared to conventional strategies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor device, the method comprising:
forming a strain-inducing semiconductor material in a cavity formed in an active region of a transistor, said active region being laterally delineated by an isolation region, said transistor comprising a gate electrode structure comprising a material system comprising a high-k dielectric material and a metal-containing cap material; and
forming a protective liner above said isolation structure and said active region including said strain-inducing semiconductor material prior to performing any wet chemical cleaning processes.

2. The method of claim 1, wherein said protective liner is deposited with a thickness of approximately 1.5-3.0 nm.

3. The method of claim 1, wherein said protective liner comprises silicon and nitrogen.

4. The method of claim 1, wherein said semiconductor device comprises a second gate electrode structure formed above said isolation region adjacent to said active region.

5. The method of claim 4, further comprising performing a cleaning process by using SPM in the presence of said protective liner formed on said gate electrode structure and said second gate electrode structure.

6. The method of claim 5, further comprising forming a resist mask so as to cover said gate electrode structure and said second gate electrode structure, forming a spacer element of a third gate electrode structure that is exposed by said resist mask and removing said resist mask during said cleaning process.

7. The method of claim 4, further comprising forming a spacer structure of said gate electrode structure and said second gate electrode structure prior to forming said strain-inducing semiconductor material.

8. The method of claim 7, further comprising forming said cavity in said active region after forming said spacer structure.

9. The method of claim 1, wherein said strain-inducing semiconductor material comprises at least one of silicon, germanium and carbon.

10. The method of claim 1, further comprising forming a metal silicide in said gate electrode structure.

11. A method, comprising:
forming a first gate electrode structure on a semiconductor region of a semiconductor device and a second gate electrode structure on an isolation region positioned adjacent to said semiconductor region, said first and second gate electrode structures comprising a material system comprising a high-k dielectric material and a metal-containing electrode material;
forming a cavity in said semiconductor region adjacent to said isolation region;
forming a semiconductor material in said cavity; and
forming a protective liner above said semiconductor region and said isolation region after forming said semiconductor material and prior to performing a wet chemical process.

12. The method of claim 11, further comprising performing said wet chemical process in the presence of said protective liner on the basis of SPM.

13. The method of claim 11, wherein said protective liner is formed with a thickness of 1.5-3.0 nm.

14. The method of claim 11, wherein said forming said first and second gate electrode structures comprises forming a sidewall spacer prior to forming said cavity so as to confine sidewalls of said material system.

15. The method of claim 11, wherein forming said protective liner comprises depositing a silicon and nitrogen containing dielectric material.

16. The method of claim 11, further comprising forming a sidewall spacer of a third gate electrode structure on the basis of said protective liner while covering said first and second gate electrode structures with a resist mask.

17. The method of claim 16, further comprising removing said resist mask when performing said wet chemical process.

18. A semiconductor device, comprising:
a first gate electrode structure formed on an active region and comprising a material system comprising a high-k dielectric material and a metal-containing electrode material;
a second gate electrode structure formed on an isolation region that is positioned adjacent to said active region, said first and second gate electrode structures comprising a spacer structure;
a strain-inducing semiconductor alloy formed in said active region and adjacent to said isolation region, said strain-inducing semiconductor alloy extending below a portion of said spacer structures of said first and second gate electrode structures;
a protective liner formed on said spacer structure and between said strain-inducing semiconductor alloy and said isolation region; and
a second spacer structure formed on said protective liner.

19. The semiconductor device of claim 18, wherein a width of said protective liner is approximately 3 nm or less.

20. The semiconductor device of claim 18, wherein said protective liner is comprised of silicon nitride.
